(19) United States
(12) Patent Application Publication
(10) Pub. No.: US 2025/0341811 A1
(43) Pub. Date: Nov. 6, 2025

(54) MECHATRONIC SYSTEM CONTROL METHOD, LITHOGRAPHIC APPARATUS CONTROL METHOD AND LITHOGRAPHIC APPARATUS

(71) Applicant: ASML Netherlands B.V., Veldhoven (NL)

(72) Inventor: Thijs Adriaan Cornelis VAN KEULEN, Eindhoven (NL)

(73) Assignee: ASML Netherlands B.V., Veldhoven (NL)

(21) Appl. No.: 18/860,879

(22) PCT Filed: Apr. 3, 2023
(86) PCT No.: PCT/EP2023/058630

§ 371 Date: Oct. 28, 2024

(30) Foreign Application Priority Data
May 9, 2022 (EP) 22172302.6

(51) Int. Cl. G05B 13/04; G03F 7/00; G05B 19/19

(52) U.S. Cl. CPC G05B 13/042; G03F 7/70725; G05B 19/19; G05B 2219/41119; G05B 2219/41434; G05B 2219/41435; G05B 2219/41443; G05B 2219/42005; G05B 2219/45028

(57) ABSTRACT

An embodiment provides a control method for controlling a mechatronic system. The method comprises providing a model of the mechatronic system, the model comprising a disturbance compensation parameter and modifying the disturbance compensation parameter by: obtaining a servo-error of the mechatronic system, obtaining a setpoint of the mechatronic system and determining, based on the setpoint and the model of the mechatronic system comprising the disturbance compensation parameter, a predicted servo-error of the mechatronic system, such that the disturbance compensation parameter is based on a correlation between the servo-error and the predicted servo-error. The method further comprises updating a feedforward transfer function of the mechatronic system based on the modified disturbance compensation parameter and continuously determining a control signal to control the mechatronic system using the updated feedforward transfer function.

### CROSS-REFERENCE TO RELATED APPLICATION

The application claims priority of EP application Ser. No. 22/172,302.6 which was filed on 9 May, 2022 and which is incorporated herein in its entirety by reference.

### FIELD

The present invention relates to a control method for controlling a mechatronic system, a lithographic apparatus control method and to a lithographic apparatus.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern (also often referred to as “design layout” or “design”) of a patterning device (e.g., a mask) onto a layer of radiation-sensitive material (resist) provided on a substrate (e.g., a wafer).

As semiconductor manufacturing processes continue to advance, the dimensions of circuit elements have continually been reduced while the amount of functional elements, such as transistors, per device has been steadily increasing over decades, following a trend commonly referred to as ‘Moore's law’. To keep up with Moore's law the semiconductor industry is chasing technologies that enable to create increasingly smaller features. To project a pattern on a substrate a lithographic apparatus may use electromagnetic radiation. The wavelength of this radiation determines the minimum size of features which are patterned on the substrate. Typical wavelengths currently in use are 365 nm (i-line), 248 nm, 193 nm and 13.5 nm. A lithographic apparatus, which uses extreme ultraviolet (EUV) radiation, having a wavelength within a range of 4 nm to 20 nm, for example 6.7 nm or 13.5 nm, may be used to form smaller features on a substrate than a lithographic apparatus which uses, for example, radiation with a wavelength of 193 nm.

Accurate control of mechatronics systems is desired in the lithographic apparatus. For example a position of the wafer table is to be accurately controlled in order to project the pattern at a desired location on the substrate. Use may be made of control systems that incorporate a feedback controller and a feedforward controller. A feedforward transfer function of the feedforward controller may take into account an expected property of the mechatronic system. Properties of the mechatronic system may however vary, such as vary over time or vary as a function of other variables, such as a wafer table position, etc. As a result of such variations, an accuracy of the feedforward transfer function of the feedforward controller may be low.

### SUMMARY

Considering the above, it is an object of the invention to provide an accurate control of a mechatronic system.

According to an embodiment of the invention, there is provided a control method for controlling a mechatronic system, the method comprising:
a) providing a model of the mechatronic system, the model comprising a disturbance compensation parameter;
b) modifying the disturbance compensation parameter by;
obtaining a servo-error of the mechatronic system;
obtaining a setpoint of the mechatronic system and determining, based on the setpoint and the model of the mechatronic system comprising the disturbance compensation parameter, a predicted servo-error of the mechatronic system,
modifying the disturbance compensation parameter based on a correlation between the servo-error and the predicted servo-error,
c) updating a feedforward transfer function of a feedforward structure of the mechatronic system based on the modified disturbance compensation parameter, and
d) continuously determining a control signal to control the mechatronic system using the updated feedforward transfer function.

According to a further embodiment of the invention, there is provided a lithographic apparatus control method comprising controlling a mechatronic system of the lithographic apparatus according to the method according to an embodiment of the present invention.

According to a yet further embodiment of the invention, there is provided a lithographic apparatus comprising a control system configured to control a mechatronic system of the lithographic apparatus, the control system being configured to control the mechatronic system according to the control method according to an embodiment of the present invention.

### BRIEF DESCRIPTION OF THE DRAWINGS

Embodiments of the invention will now be described, by way of example only, with reference to the accompanying schematic drawings, in which:

FIG. 1 depicts a schematic overview of a lithographic apparatus as may be employed according to an embodiment of the invention;

FIG. 2 depicts a detailed view of a part of the lithographic apparatus of FIG. 1;

FIG. 3 schematically depicts a position control system as part of a positioning system as may be employed according to an embodiment of the invention;

FIG. 4 depicts a block schematic control diagram based on which the control method according to an embodiment will be explained;

FIGS. 5A-5C respectively depict a top view, a diagram of x-direction setpoint trajectory versus time and a diagram of y-direction setpoint trajectory versus time of a lithographic apparatus scanning pattern; and

FIG. 6 depicts a flow diagram of the control method according to an embodiment of the invention.

### DETAILED DESCRIPTION

In the present document, the terms “radiation” and “beam” are used to encompass all types of electromagnetic radiation, including ultraviolet radiation (e.g. with a wavelength of 365, 248, 193, 157or 126 nm) and EUV (extreme ultra-violet radiation, e.g. having a wavelength in the range of about 5-100 nm).

The term “reticle”, “mask” or “patterning device” as employed in this text may be broadly interpreted as referring to a generic patterning device that can be used to endow an incoming radiation beam with a patterned cross-section, corresponding to a pattern that is to be created in a target portion of the substrate. The term “light valve” can also be used in this context. Besides the classic mask (transmissive or reflective, binary, phase-shifting, hybrid, etc.), examples of other such patterning devices include a programmable mirror array and a programmable LCD array.

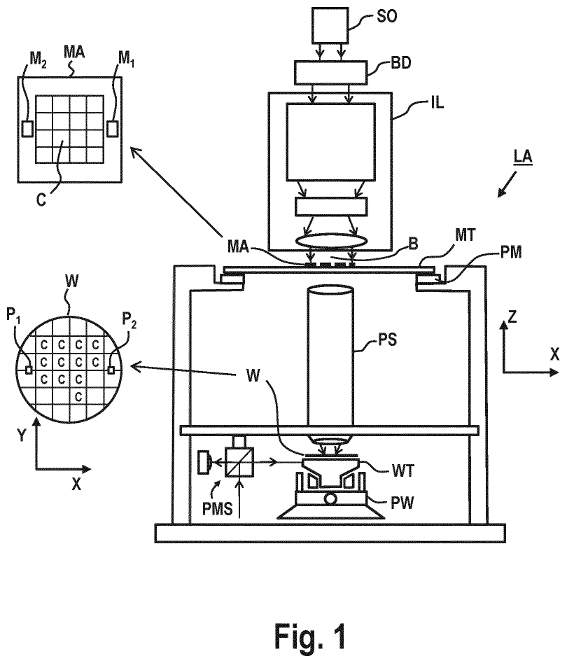

FIG. 1 schematically depicts a lithographic apparatus LA. The lithographic apparatus LA

includes an illumination system (also referred to as illuminator) IL configured to condition a radiation beam B (e.g., UV radiation, DUV radiation or EUV radiation), a mask support (e.g., a mask table) MT constructed to support a patterning device (e.g., a mask) MA and connected to a first positioner PM configured to accurately position the patterning device MA in accordance with certain parameters, a substrate support (e.g., a wafer table) WT constructed to hold a substrate (e.g., a resist coated wafer) W and connected to a second positioner PW configured to accurately position the substrate support in accordance with certain parameters, and a projection system (e.g., a refractive projection lens system) PS configured to project a pattern imparted to the radiation beam B by patterning device MA onto a target portion C (e.g., comprising one or more dies) of the substrate W.

In operation, the illumination system IL receives a radiation beam from a radiation source SO, e.g. via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

The lithographic apparatus LA may be of a type wherein at least a portion of the substrate may be covered by a liquid having a relatively high refractive index, e.g., water, so as to fill a space between the projection system PS and the substrate W—which is also referred to as immersion lithography. More information on immersion techniques is given in U.S. Pat. No. 6,952,253, which is incorporated herein by reference.

The lithographic apparatus LA may also be of a type having two or more substrate supports WT (also named “dual stage”). In such “multiple stage” machine, the substrate supports WT may be used in parallel, and/or steps in preparation of a subsequent exposure of the substrate W may be carried out on the substrate W located on one of the substrate support WT while another substrate W on the other substrate support WT is being used for exposing a pattern on the other substrate W.

In addition to the substrate support WT, the lithographic apparatus LA may comprise a measurement stage. The measurement stage is arranged to hold a sensor and/or a cleaning device. The sensor may be arranged to measure a property of the projection system PS or a property of the radiation beam B. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate support WT is away from the projection system PS.

In operation, the radiation beam B is incident on the patterning device, e.g. mask, MA which is held on the mask support MT, and is patterned by the pattern (design layout) present on patterning device MA. Having traversed the patterning device MA, the radiation beam B passes through the projection system PS, which focuses the beam onto a target portion C of the substrate W. With the aid of the second positioner PW and a position measurement system IF, the substrate support WT can be moved accurately, e.g., so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions. Substrate alignment marks P1, P2 are known as scribe-lane alignment marks when these are located between the target portions C.

To clarify the invention, a Cartesian coordinate system is used. The Cartesian coordinate system has three axes, i.e., an x-axis, a y-axis and a z-axis. Each of the three axes is orthogonal to the other two axes. A rotation around the x-axis is referred to as an Rx-rotation. A rotation around the y-axis is referred to as an Ry-rotation. A rotation around about the z-axis is referred to as an Rz-rotation. The x-axis and the y-axis define a horizontal plane, whereas the z-axis is in a vertical direction. The Cartesian coordinate system is not limiting the invention and is used for clarification only. Instead, another coordinate system, such as a cylindrical coordinate system, may be used to clarify the invention. The orientation of the Cartesian coordinate system may be different, for example, such that the z-axis has a component along the horizontal plane.

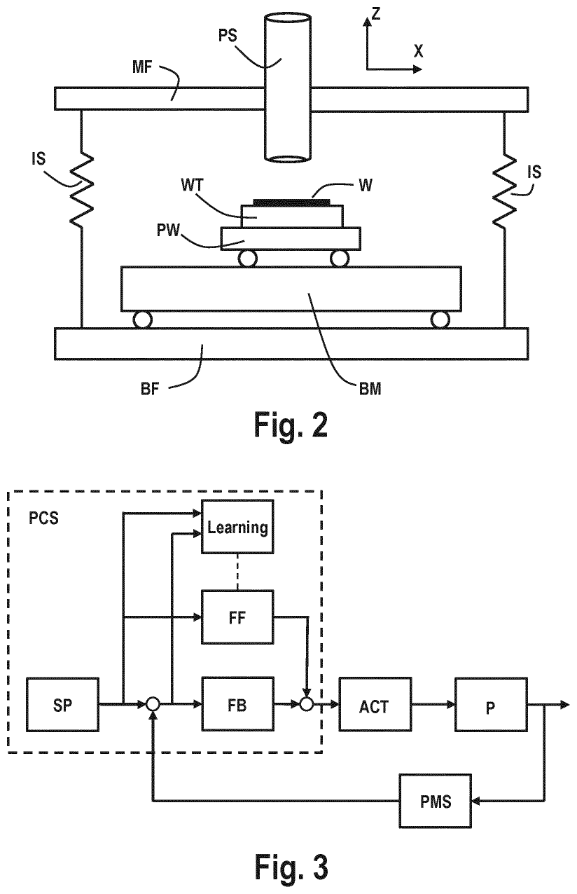

FIG. 2 shows a more detailed view of a part of the lithographic apparatus LA of FIG. 1. The lithographic apparatus LA may be provided with a base frame BF, a balance mass BM, a metrology frame MF and a vibration isolation system IS. The metrology frame MF supports the projection system PS. Additionally, the metrology frame MF may support a part of the position measurement system PMS. The metrology frame MF is supported by the base frame BF via the vibration isolation system IS. The vibration isolation system IS is arranged to prevent or reduce vibrations from propagating from the base frame BF to the metrology frame MF.

The second positioner PW is arranged to accelerate the substrate support WT by providing a driving force between the substrate support WT and the balance mass BM. The driving force accelerates the substrate support WT in a desired direction. Due to the conservation of momentum, the driving force is also applied to the balance mass BM with equal magnitude, but at a direction opposite to the desired direction. Typically, the mass of the balance mass BM is significantly larger than the masses of the moving part of the second positioner PW and the substrate support WT.

In an embodiment, the second positioner PW is supported by the balance mass BM. For example, wherein the second positioner PW comprises a planar motor to levitate the substrate support WT above the balance mass BM. In another embodiment, the second positioner PW is supported by the base frame BF. For example, wherein the second positioner PW comprises a linear motor and wherein the second positioner PW comprises a bearing, like a gas bearing, to levitate the substrate support WT above the base frame BF.

The position measurement system PMS may comprise any type of sensor that is suitable to determine a position of the substrate support WT. The position measurement system PMS may comprise any type of sensor that is suitable to determine a position of the mask support MT. The sensor may be an optical sensor such as an interferometer or an encoder. The position measurement system PMS may comprise a combined system of an interferometer and an encoder. The sensor may be another type of sensor, such as a magnetic sensor, a capacitive sensor or an inductive sensor. The position measurement system PMS may determine the position relative to a reference, for example the metrology frame MF or the projection system PS. The position measurement system PMS may determine the position of the substrate table WT and/or the mask support MT by measuring the position or by measuring a time derivative of the position, such as velocity or acceleration.

The position measurement system PMS may comprise an encoder system. An encoder system is known from for example, United States patent application US2007/0058173A1, filed on Sep. 7, 2006, hereby incorporated by reference. The encoder system comprises an encoder head, a grating and a sensor. The encoder system may receive a primary radiation beam and a secondary radiation beam. Both the primary radiation beam as well as the secondary radiation beam originate from the same radiation beam, i.e., the original radiation beam. At least one of the primary radiation beam and the secondary radiation beam is created by diffracting the original radiation beam with the grating. If both the primary radiation beam and the secondary radiation beam are created by diffracting the original radiation beam with the grating, the primary radiation beam needs to have a different diffraction order than the secondary radiation beam. Different diffraction orders are, for example, +1^{st} order, −1^{st} order, +2^{nd} order and −2^{nd} order. The encoder system optically combines the primary radiation beam and the secondary radiation beam into a combined radiation beam. A sensor in the encoder head determines a phase or phase difference of the combined radiation beam. The sensor generates a signal based on the phase or phase difference. The signal is representative of a position of the encoder head relative to the grating. One of the encoder head and the grating may be arranged on the substrate structure WT. The other of the encoder head and the grating may be arranged on the metrology frame MF or the base frame BF. For example, a plurality of encoder heads is arranged on the metrology frame MF, whereas a grating is arranged on a top surface of the substrate support WT. In another example, a grating is arranged on a bottom surface of the substrate support WT, and an encoder head is arranged below the substrate support WT.

The position measurement system PMS may comprise an interferometer system. An interferometer system is known from, for example, U.S. Pat. No. 6,020,964, filed on Jul. 13, 1998, hereby incorporated by reference. The interferometer system may comprise a beam splitter, a mirror, a reference mirror and a sensor. A beam of radiation is split by the beam splitter into a reference beam and a measurement beam. The measurement beam propagates to the mirror and is reflected by the mirror back to the beam splitter. The reference beam propagates to the reference mirror and is reflected by the reference mirror back to the beam splitter. At the beam splitter, the measurement beam and the reference beam are combined into a combined radiation beam. The combined radiation beam is incident on the sensor. The sensor determines a phase or a frequency of the combined radiation beam. The sensor generates a signal based on the phase or the frequency. The signal is representative of a displacement of the mirror. In an embodiment, the mirror is connected to the substrate support WT. The reference mirror may be connected to the metrology frame MF. In an embodiment, the measurement beam and the reference beam are combined into a combined radiation beam by an additional optical component instead of the beam splitter.

The first positioner PM may comprise a long-stroke module and a short-stroke module. The short-stroke module is arranged to move the mask support MT relative to the long-stroke module with a high accuracy over a small range of movement. The long-stroke module is arranged to move the short-stroke module relative to the projection system PS with a relatively low accuracy over a large range of movement. With the combination of the long-stroke module and the short-stroke module, the first positioner PM is able to move the mask support MT relative to the projection system PS with a high accuracy over a large range of movement. Similarly, the second positioner PW may comprise a long-stroke module and a short-stroke module. The short-stroke module is arranged to move the substrate support WT relative to the long-stroke module with a high accuracy over a small range of movement. The long-stroke module is arranged to move the short-stroke module relative to the projection system PS with a relatively low accuracy over a large range of movement. With the combination of the long-stroke module and the short-stroke module, the second positioner PW is able to move the substrate support WT relative to the projection system PS with a high accuracy over a large range of movement.

The first positioner PM and the second positioner PW each are provided with an actuator to move respectively the mask support MT and the substrate support WT. The actuator may be a linear actuator to provide a driving force along a single axis, for example the y-axis. Multiple linear actuators may be applied to provide driving forces along multiple axis. The actuator may be a planar actuator to provide a driving force along multiple axis. For example, the planar actuator may be arranged to move the substrate support WT in 6 degrees of freedom. The actuator may be an electro-magnetic actuator comprising at least one coil and at least one magnet. The actuator is arranged to move the at least one coil relative to the at least one magnet by applying an electrical current to the at least one coil. The actuator may be a moving-magnet type actuator, which has the at least one magnet coupled to the substrate support WT respectively to the mask support MT. The actuator may be a moving-coil type actuator which has the at least one coil coupled to the substrate support WT respectively to the mask support MT. The actuator may be a voice-coil actuator, a reluctance actuator, a Lorentz-actuator or a piezo-actuator, or any other suitable actuator.

The lithographic apparatus LA comprises a position control system PCS as schematically depicted in FIG. 3. The position control system PCS comprises a setpoint generator SP, a feedforward controller FF and a feedback controller FB. The position control system PCS provides a drive signal to the actuator ACT. The actuator ACT may be the actuator of the first positioner PM or the second positioner PW. The actuator ACT drives the plant P, which may comprise the substrate support WT or the mask support MT. An output of the plant P is a position quantity such as position or velocity or acceleration. The position quantity is measured with the position measurement system PMS. The position measurement system PMS generates a signal, which is a position signal representative of the position quantity of the plant P. The setpoint generator SP generates a signal, which is a reference signal representative of a desired position quantity of the plant P. For example, the reference signal represents a desired trajectory of the substrate support WT. A difference between the reference signal and the position signal forms an input for the feedback controller FB. Based on the input, the feedback controller FB provides at least part of the drive signal for the actuator ACT. The reference signal may form an input for the feedforward controller FF. Based on the input, the feedforward controller FF provides at least part of the drive signal for the actuator ACT. The feedforward FF may make use of information about dynamical characteristics of the plant P, such as mass, stiffness, resonance modes and eigenfrequencies.

The servo performance of mechatronic systems in a lithographic apparatus, for example in Wafer Stages, WS's, and Reticle Stages, RS, of the lithographic apparatus, may rely on Feed Forward, FF, compensation of the mechanical structure, actuation, and known disturbances. The main disturbance to the control loop may be the excitation of the mechanical structure by the setpoint trajectory. Typical FF compensation of the setpoint trajectory may includes velocity, acceleration, jerk, snap, and compliance compensation. Besides, disturbance forces of, for example, a cable slab, Eddy current damping and reluctance in the Long Stroke, LoS, and dynamic link and cooling water pressure pulse in the Short Stroke, SS, may be known. Typically a large part of the actuation forces come from FF and disturbance compensation requiring only minor adjustments by FeedBack, FB, control. So, appropriate parametrization of the compensation parameters may be desired to achieve accurate tracking performance.

Calibration of the compensation parameters may not be straightforward, however. Production tolerances may lead to machine to machine variations. For instance, the stages may suffer from motor constant variations caused by: saturation of back iron (current dependent), coil position with respect to magnets, magnet strength variations, magnet plate flatness and non-linearities in the amplifiers. Also temperature dependent magnet field strength and amplifier components may play a role. Moreover, the stage mass, inertia and dynamics may depend on the position for example due to the roll-off of the cable slab. Different lithography applications may lead to significant variations in the wafer mass.

Furthermore, the actuators of the stages may not be situated in the Centre of Gravity, CoG, but are distributed over the stage. Hence, a decoupling matrix may be applied to be able to use decentralized control, i.e. to be able to employ 6 independent single input, single output, SISO, controllers, one for each rigid-body logical direction. Due to movements of stages in a fixed measurement system, the decoupling matrices may become position dependent. Moreover, the LoS planar actuators may use a commutation measurement system which may be prone to sensor drift and slow thermal dynamics. Note that, the 3phase motor commutation may also generate force disturbance in case of commutation offsets.

Also, accurate time alignment between the FF and FB control path may be needed, as well as between peripherals such as LoS and SS, i.e. to compensate for delay in amplifiers, sensors and communication. Sub-sample time alignment may thereby be required to meet the servo error specifications which may be approximated by compensation based on higher-order time derivatives, i.e. jerk FF to compensate for time mismatch of the acceleration FF compensation.

To summarize, calibration of FF and disturbance compensation parameters may not be straightforward due position and load dependency, machine to machine variations, and time-varying effects. In a known solution, all compensation parameters may be calibrated and then kept constant during normal operation. The applied calibration method for the FF parameters may be based on a data-based calibration method. The decoupling parameters may require fine tuning which may be done by a data-based calibration method.

Besides accurate feed forward control, the system may require diagnostic functionality to monitor system degradation during normal operation. The diagnostic functionality may monitor the servo error MA and MSD values. The methods that may improve the servo performance may also be suitable to improve the diagnostics by being able to pin-point to a specific disturbance source causing a servo error.

Learning strategies have been subject of investigation for many years. Since the WS executes similar trajectories iteratively, for example expose scans, the focus may be to employ an optimization procedure in real-time (i.e. during machine operation) by exploiting the iterative nature of WS scans.

The concept of Iterative Learning Control (ILC) may apply to systems that repeat the same setpoint trajectory. ILC approaches generate a force trajectory which may attempt to compensate the control error based on an estimate of the controlled system. So, ILC may rely on a system description and fixed setpoint trajectory and may not exploit explicit knowledge of the disturbance source. An obstacle for the application of online ILC strategies may be the robustness to setpoint variations, i.e. to deal with nonrepetitive (thermal) corrections applied to the expose scan setpoint and to align with other parts of the machine such as the source, reticle and POB.

Prior art learning strategies may rely on a repeating setpoint trajectory and may be unable to remove structured servo errors online in a lithographic apparatus while providing the required robustness to setpoint variations.

Although very high servo performance may be reached in a lithographic apparatus, further improvements may be desired.

The present invention aims to achieve further improvement of the servo control performance (improved overlay or higher acceleration setpoints) by enabling online adaptations of the feed forward, disturbance compensation and decoupling parameters that are subject to time-variations. Online adaptations is also referred to as “learning”. Position dependent parameters can be compensated for by field-to-field optimization during an constant velocity expose scan by exploiting the acceleration phase to learn the local optimal parameter setting.

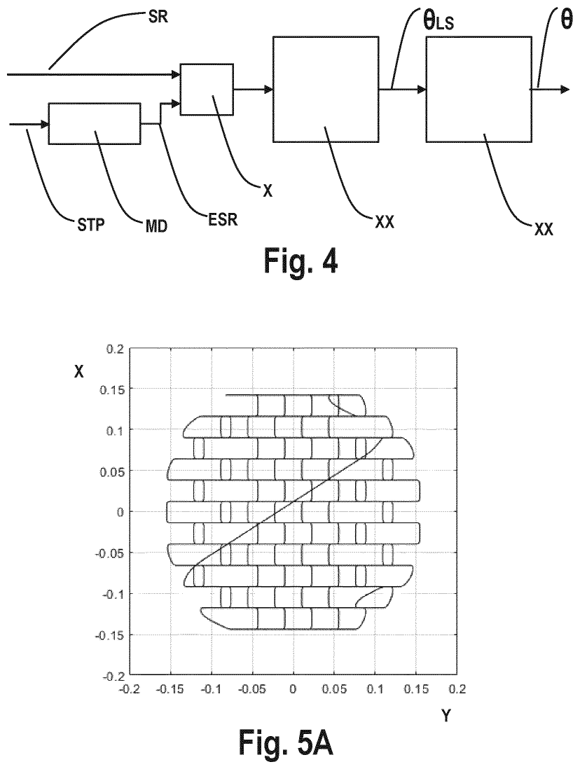

FIG. 4 depicts a block schematic view based on which an updated disturbance compensation parameter is determined. A setpoint STP is input to a model MD. The setpoint may be the setpoint STP as generated by the setpoint generator SP and provided to the control system, such as the control system in accordance with FIG. 3. The Model MD determines from the setpoint STP a predicted servo error ESR. The model MD may comprise a reciprocal of the plant behaviour, as well as characteristics of the feedback controller behaviour, hence enabling to predict a servo-error of the mechatronic system based on the setpoint. Further, the setpoint STP is provided to the control system, whereby a servo-error SR is measured. The servo-error SR is to be understood as the input to the feedback controller FB, i.e. a difference between the setpoint STP and the feedback signal as derived by PMS from the output of the plant P. The predicted servo-error ESR is then correlated with the measured servo-error SR, which may be performed as follows: the predicted servo error ESR and the measured servo-error SR are multiplied, as represented in FIG. 4 by X, following which the correlation is calculated, e.g. over N successive time instants, N being a natural number N>1. In the determination of the correlation, the following formula (1) may be made use of:

$$\frac{C}{N} {\sum }_{t = 1}^{N} {\hat{e}}^{T} e \qquad ( 1 )$$

Wherein ê represents the predicted servo error signal ESR as derived using the model and e represents the measured servo-error signal SR. The variable C is a constant that relates to a magnitude of the prediction error, horizon length and excitation properties of the setpoint. Variable C may be calibrated for a worst case setpoint with known maximal excitation.

As a result, an estimate of the disturbance compensation parameter θ_{LS} is obtained. The estimate of the disturbance compensation parameter may for example comprise a least squares estimate. The disturbance compensation parameter θ may then determined from the estimate θ_{LS}, at successive time steps, using for instance a steepest descent optimization with step size c to converge to an optimum disturbance compensation parameter θ, using following formula (2):

$$( t + 1 ) = θ ( t ) - c {θ}_{LS} ( t ) \qquad ( 2 )$$

With each iteration, using the determined disturbance compensation parameter θ, the feedforward transfer function of the feedforward structure of the mechatronic system is updated and a control signal is determined to control the mechatronic system using the updated feedforward transer function. The feedforward transfer function of the feedforward structure of the mechatronic system may comprise a reciprocal plant behaviour, for example an inverse mass and a compliance of the mechatronic structure.

The modified disturbance compensation parameter may be determined repetitively by repeating the steps of:
obtaining the servo-error of the mechatronic system;
obtaining the setpoint of the mechatronic system and determining, based on the setpoint and the model of the mechatronic system comprising the disturbance compensation parameter, the predicted servo-error of the mechatronic system,
modifying the disturbance compensation parameter based on the correlation between the servo-error and the predicted servo-error, and
updating the feedforward transfer function of the feedforward structure of the mechatronic system based on the modified disturbance compensation parameter.
the control signal to control the mechatronic system is continuously determined using the repetitively updated feedforward transfer function. The model may be updated based on the modified disturbance compensation parameter, thereby to enable to provide a more accurate determination of the predicted servo-error, which may promote a convergence towards a suitable value of the disturbance compensation parameter.

With N previous repetitions, N being a natural number, the optimization may be performed using plural iterations, thus to optimize the disturbance control parameter over time. The servo error and the predicted servo error may be combined using the least squares method, providing an analytical solution, when assuming that the servo error depends linearly on the compensation parameter.

A time scale of the N previous repetitions and/or a time scale of the updating of the modified disturbace compensation parameter may be set to exceed a time scale of a repetitive pattern in the setpoint and/or a time scale of the feedback controlled system, e.g. the time scale indicated by the bandwidth of the feedback controlled system. As a result, the optimization may be performed over a time scale which is long relative to the time scale of repetitive patterns in the setpoint and/or the bandwidth of the feedback controlled system, which may avoid that the optimization is disturbed by the dynamics of the setpoint and/or the feedback controlled system.

The disturbance control parameter may comprise any parameter that may exhibit a change, fluctuation, tolerance etc. For example, the disturbance control parameter may comprise a mass of the mechatronic system.

The control signal as determined by the above described method may be a feedforward signal generated by a feedforward structure of the control system, such as the feedforward FF of the position control system described with reference to FIG. 3. The feedforward signal may represent a feedforward force of the mechatronic system. Accordingly, the feedforward signal may be accurately determined, taking account of a change, fluctuation, tolerance, etc. in the mechatronic system. As the feedforward control may provide a relatively fast control, an accuracy of the feedforward control may be enhanced by the recursive method described above. Hence, in addition to the feedforward being relatively fast, the feedforward may also provide a relatively accurate control, taking account of the mentioned changes, fluctuations, tolerances, etc.

The control signal as determined by the above described method may be a feedforward signal generated by a feedforward structure of the control system, the feedforward structure providing a feedforward signal from a first mechatronic subsystem to a second mechatronic subsystem of the mechatronic system. For example, the first mechatronic subsystem may comprise the support, e.g. the support of the patterning device. while the second mechatronic subsystem may comprise the substrate table. Hence, a disturbance by a movement of the support onto the substrate table positioning may be accurately controlled, in that the determination of the disturbance compensation parameter may enable an accurate feedforward thereby taking account of variabes in disturbance by the support on the substrate table.

The mechatronic system may comprise an actuator, such as an electromagnetic actuator. The disturbance compensation parameter may be used to take account of fluctuations or tolerances, such as an actuator force constant varying or being position dependent, and a commutation position parameter between magnets and coil.

The control method as described in the present document may be used for controlling a mechatronic system of a lithographic apparatus.

For example, the control signal may comprise a feedforward signal of the lithographic apparatus. The disturbance parameter may be comprised in a feedforward structure that generates the feedforward signal. For example, the mechatronic system may comprise a substrate table of the lithographic apparatus, whereby the feedforward structure is configured to provide a feedforward signal representing the feedforward force of the substrate table.

As an other example, the control signal as determined by the above described method may be a feedforward signal generated by a feedforward structure of the control system, the feedforward structure providing a feedforward signal from a first mechatronic subsystem of the lithographic apparatus to a second mechatronic subsystem of the lithographic apparatus. For example, the first mechatronic subsystem may comprise the support that supports the patterning device while the second mechatronic subsystem may comprise the substrate table. Hence, a disturbance by a movement of the support onto the substrate table positioning may be accurately controlled, in that the determination of the disturbance compensation parameter may enable an accurate feedforward signal thereby taking account of variabes in disturbance by the support on the substrate table.

Other subsystems of the lithographic apparatus, for which the present control method may be used, may include positioning of optical elements. For example, a position of an optical element such as a lens or a mirror may be controlled by the method described in the present document.

Basically the present control method may be applied to all disturbance compensations that use the setpoint signal as input, such as for example a friction, an eddy current damping, a reluctance, a mass, a jerk, a snap, a compliance, pressure pulses of cooling water, etc.

Besides, theoretically the method can also be used for parameters in the feedback loop, for example the decoupling parameters in the GB matrix. This would require not only updating the parameters in the FF structure but also in the model that generates the servo error prediction.

By the method according to the present invention, a control of the mechatronic system may be made more accurate. Variable parameters in the mechatronic system may be taken into account, whereby a value of the variable parameter is learned by comparing the modelled servo error to the measured servo error. A correlation between the modelled servo error and the measured servo error is maximized, in that the disturbance compensation parameter is learned to a value which maximizes the correlation. The disturbance compensation parameter is used in the controlling of the mechatronic system, enabling to take account of variables in the mechatronic system, such as a varying or position dependent actuator force constant, a varying mass, etc. The correlation may be determined over a time span which exceeds a time span of a periodic movement of the mechatronic system, hence enabling to determine a suitable value for the disturbance compensation parameter as the mechatronic system is subject to e.g. cycles of movement such as acceleration, constant velocity, deceleration, etc. A variation of the variable parameter over time may be taken into account. For example, in the case of a position dependent parameter, such as a dependency on a stage position, the disturbance compensation parameter may be continuously adapted according to the present control method, to take account of the variation in the parameter as the position (e.g. the position of the stage) changes. The control according to the present invention may be particularly useful in a feedforward, in that an accurate feedforward control may be determined, in that a variable parameter in the mechatronic system, such as a variable mass, a position dependency, a variable motor force constant, etc. is taken into account. The variable parameter would conventionally result in an inaccuracy in the feedforward signal, which may be reduced by the present invention. The disturbance compensation parameter is learned to take account of the variable parameter, which may thereby enhance an accuracy of the feedforward. As a result, a corrective action by the feedback control, as may otherwise be required to compensate for the variable parameter comprised in a feedforward path, may be reduced, enabling to enhance an accuracy of the control of the mechatronic system.

Accordingly, robust online learning may result as described, e.g. from the use of instrumental variables, based on the model of the control system Ĥ with suboptimal parameters \hat{θ}. This model may provide an estimate, based on the actual setpoint STP, of an servo error signal ê typical for imperfect calibration of the parameter that is subject to optimization. Correlation of the measured servo error e with this predicted servo error ê, indicates the room for improvement. The correlation can be evaluated in a receding horizon fashion, e.g. over the last N time steps. The latter may be considered equivalent to providing least-squares estimate θ_{LS} of the parameter deviation from optimal on the considered past data. The disturbance parameter θ may then be updated, at each time step, using for instance a steepest descent optimization with step size c to converge to the optimal value.

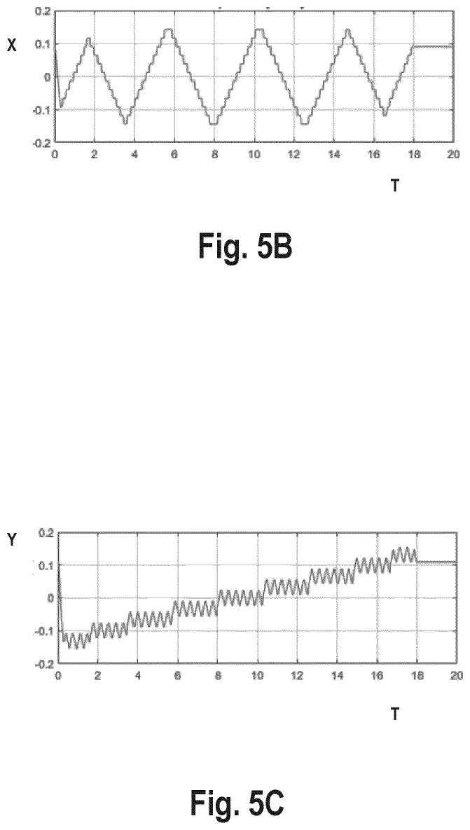

The learning strategy may be implemented and experimentally validated to demonstrate the potential by compensating simultaneously for 6 parameters during an expose scan, see FIG. 5A-5C, namely:
mass (motor force constant) FF parameter in x- and y-direction
time-alignment between FF and FB in x- and y-direction
position offset for the planar actuator commutation in x- and y-direction.

FIG. 5A depicts a top view of a substrate table setpoint trajectory, whereby the substrate table is moved in a horizontal plane. FIG. 5B and 5C respectively depict an x-direction component and an y-direction component of the setpoint trajectory of FIG. 5A. In FIG. 5A, the x-direction is represented by the horizontal axis and the y-component by the vertical axis. After leaning a feedforward of the substrate table control, i.e. after determining the disturbance compensation parameter as described in the present document, a servo error in x-direction and a servo error in y-direction may be reduced.

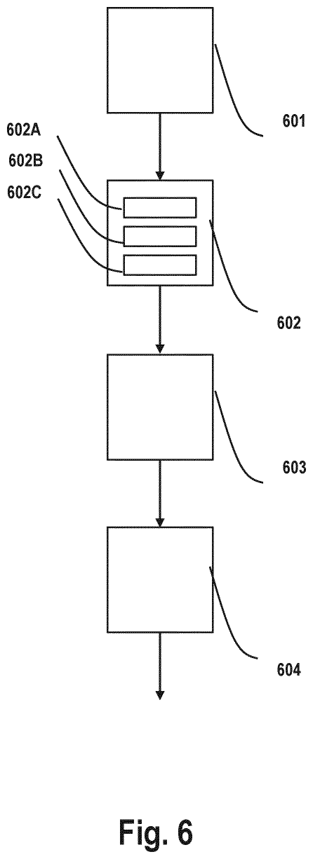

The control method may be summarized as follows, referring to FIG. 6:

A control method for controlling a mechatronic system, the method comprising:
a) providing, 601, a model of the mechatronic system, the model comprising a disturbance compensation parameter;
b) modifying, 602, the disturbance compensation parameter by;
obtaining, 602A, a servo-error of the mechatronic system;
obtaining, 602B, a setpoint of the mechatronic system and determining, based on the setpoint and the model of the mechatronic system comprising the disturbance compensation parameter, a predicted servo-error of the mechatronic system,
modifying, 602C, the disturbance compensation parameter based on a correlation between the servo-error and the predicted servo-error,
c) updating, 603, the feedforward transfefr function of a feedforward structure of the mechatronic system based on the modified disturbance compensation parameter, and
d) continuously determining, 604, a control signal to control the mechatronic system using the updated feedforward transfer function.

Although specific reference may be made in this text to the use of a lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools. Such a lithographic tool may use vacuum conditions or ambient (non-vacuum) conditions.

Although specific reference may have been made above to the use of embodiments of the invention in the context of optical lithography, it will be appreciated that the invention, where the context allows, is not limited to optical lithography and may be used in other applications, for example imprint lithography.

Where the context allows, embodiments of the invention may be implemented in hardware, firmware, software, or any combination thereof. Embodiments of the invention may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic storage media; optical storage media; flash memory devices; electrical, optical, acoustical or other forms of propagated signals (e.g. carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc. and in doing that may cause actuators or other devices to interact with the physical world.

While specific embodiments of the invention have been described above, it will be appreciated that the invention may be practiced otherwise than as described. The descriptions above are intended to be illustrative, not limiting.

1-15. (canceled)

16. A method comprising:
providing a model of a mechatronic system, the model comprising a disturbance compensation parameter;
modifying the disturbance compensation parameter by:
obtaining a servo-error of the mechatronic system,
obtaining a setpoint of the mechatronic system and determining, based on the setpoint and the model of the mechatronic system comprising the disturbance compensation parameter, a predicted servo-error of the mechatronic system, and
wherein the disturbance compensation parameter is based on a correlation between the servo-error and the predicted servo-error;
updating a feedforward transfer function of a feedforward structure of the mechatronic system based on the modified disturbance compensation parameter; and
continuously determining a control signal to control the mechatronic system using the updated feedforward transfer function.

17. The method of claim 16, wherein:
the providing and the modifying are repeated to repetitively update the feedforward transfer function; and
the continuously determining the mechatronic system is controlled using the repetitively updated feedforward transfer function.

18. The method of claim 17, wherein the modifying further comprises updating the model based on the modified disturbance compensation parameter.

19. The method of claim 17, wherein the disturbance compensation parameter is modified based on the correlation between the servo-error and the predicted servo-error at N previous repetitions, N being a natural number>1.

20. The method of claim 19, wherein the correlation between the servo-error and the predicted servo-error at N previous repetitions are combined using a least squares method.

21. The method of claim 17, wherein a time scale of the N previous repetitions is set to exceed a time scale of a repetitive pattern in the setpoint.

22. The method of claim 17, wherein:
the control signal is a feedforward signal generated by the feedforward structure and representing a feedforward force of the mechatronic system; and
the disturbance compensation parameter is comprised in the feedforward transfer function of the feedforward structure.

23. The method of claim 16, wherein:
the mechatronic system comprises dual mechatronic subsystems,
the model of the mechatronic system comprises the feedforward structure from one of the mechatronic subsystems to the other one of the mechatronic subsystems, and
the disturbance compensation parameter is comprised in the feedforward transfer function of the feedforward structure.

24. The method of claim 16, wherein the mechatronic system comprises an actuator, such as an electromagnetic actuator.

25. A lithographic apparatus comprising:
a control system configured to control a mechatronic system of the lithographic apparatus,
wherein the control system is configured to control the mechatronic system according to the control method of claim 16.

26. The lithographic apparatus of claim 25, comprising:
a feedforward structure configured to provide a feedforward force, and
wherein the disturbance compensation parameter is comprised in the feedforward structure.

27. The lithographic apparatus of claim 26, wherein the mechatronic system comprises:
a substrate table configured to hold a substrate,
wherein the feedforward structure is configured to provide the feedforward force on the substrate table.

28. The lithographic apparatus of claim 25, wherein the mechatronic system comprises:
dual mechatronic subsystems, the lithographic apparatus comprising a feedforward structure from one of the mechatronic subsystems to the other one of the mechatronic subsystems, and
wherein the disturbance compensation parameter is comprised in the feedforward structure.

29. The lithographic apparatus of claim 28, comprising:
a substrate table configured to hold a substrate; and
a support to support a patterning device,
wherein the one of the mechatronic subsystems comprises the support and the other one of the mechatronic subsystems comprises the substrate table.
